(19) United States
(12) Patent Application Publication
(10) Pub. No.: US 2026/0136698 A1
(43) Pub. Date: May 14, 2026

(54) PHOTOELECTRIC MODULE AND METHOD OF MANUFACTURING THE SAME

(71) Applicant: EPISTAR CORPORATION, Hsinchu (TW)

(72) Inventors: Te-Chung WANG, Hsinchu (TW); Shao-You DENG, Hsinchu (TW)

(21) Appl. No.: 19/363,977

(22) Filed: Oct. 21, 2025

Related U.S. Application Data
(60) Provisional application No. 63/720,274, filed on Nov. 14, 2024.

(30) Foreign Application Priority Data
Aug. 29, 2025 (TW) 114133034

(51) Int. Cl. H10F 55/255; H10F 71/00; H10F 77/40

(52) U.S. Cl. CPC H10F 55/255; H10F 71/139; H10F 77/413

(57) ABSTRACT

A manufacturing method for a photoelectric module is provided, which includes the following steps. A temporary substrate, a first lens, and a second lens are provided, wherein the first lens and the second lens are embedded in the temporary substrate. A first photoelectric element is arranged on the first lens. A second photoelectric element is arranged on the second lens. An electrical connection structure is formed on the first and second photoelectric elements. The temporary substrate is removed to expose the first lens and the second lens.

### CROSS-REFERENCE TO RELATED APPLICATIONS

This application claims priority to, and the benefit of, Provisional Application Serial No. 63/720,274 filed on November 14, 2024, and Taiwan Patent Application Number 114133034 filed on August 29, 2025, the entirety of which are hereby incorporated by reference.

### TECHNICAL FIELD

The present disclosure relates to a photoelectric module, and more particularly, to a method of manufacturing a photoelectric module.

### BACKGROUND

As high-performance computing (HPC) and data communication (Datacom) continue to evolve, optical communication is increasingly regarded as a potential data transmission method capable of replacing electrical transmission.

### SUMMARY

One embodiment of the present disclosure provides a method of manufacturing a photoelectric module. The method includes: providing a temporary substrate, a first lens, and a second lens, wherein the first lens and the second lens are embedded in the temporary substrate; arranging a first photoelectric element on the first lens; arranging a second photoelectric element on the second lens; forming an electrical connection structure on the first and second photoelectric elements; and removing the temporary substrate to expose the first lens and the second lens.

### BRIEF DESCRIPTION OF THE DRAWINGS

The embodiments of the present disclosure can be more fully understood by referring to the following detailed description in conjunction with the accompanying drawings. It should be noted that certain components may not be drawn to scale. For clarity, the dimensions of some components may be exaggerated or reduced.

FIG. 1 illustrates a photoelectric module according to one embodiment of the present disclosure.

FIGS. 2 to 6 illustrate a manufacturing process of a photoelectric module as shown in FIG. 1.

FIG. 7 illustrates a photoelectric module according to another embodiment of the present disclosure.

FIGS. 8 to 12 illustrate a manufacturing process of a photoelectric module as shown in FIG. 7.

FIGS. 13A and 13B illustrate a photoelectric unit according to different embodiments.

FIGS. 14 and 15 illustrate a side view and a bottom view, respectively, of a photoelectric unit according to one embodiment.

FIGS. 16A to 16D illustrate an arrangement of the photoelectric units according to different embodiments.

FIGS. 17A to 17G illustrate a photoelectric system according to different embodiments.

### DETAILED DESCRIPTION OF THE APPLICATION

The following embodiments are described with reference to the accompanying drawings, in which like reference numerals refer to similar or identical elements. In the drawings, the shapes or thicknesses of elements may be exaggerated or reduced for clarity. It should be noted that elements not shown in the drawings or not described in the specification may be in forms known to those skilled in the art. In some figures, certain components and/or reference numerals may be omitted. Similar reference numerals indicate similar elements across the figures. The following description and the accompanying drawings are provided for illustrative purposes and are not intended to be limiting. It is contemplated that features and components described in one embodiment may be advantageously incorporated into another embodiment without further elaboration. Furthermore, additional layers/structures or steps may be incorporated into the embodiments described herein. For example, the description “forming a second layer/structure on a first layer/structure” may include embodiments in which the first and second layers/structures are in direct contact, or embodiments in which the first and second layers/structures are in indirect contact, i.e., with one or more additional layers/structures in between. In addition, the spatial relationships between the first and second layers/structures may vary depending on the operation or use of the device. The term “layer” or “structure” is not limited to a single layer or structure and may include multiple sub-layers or sub-structures.

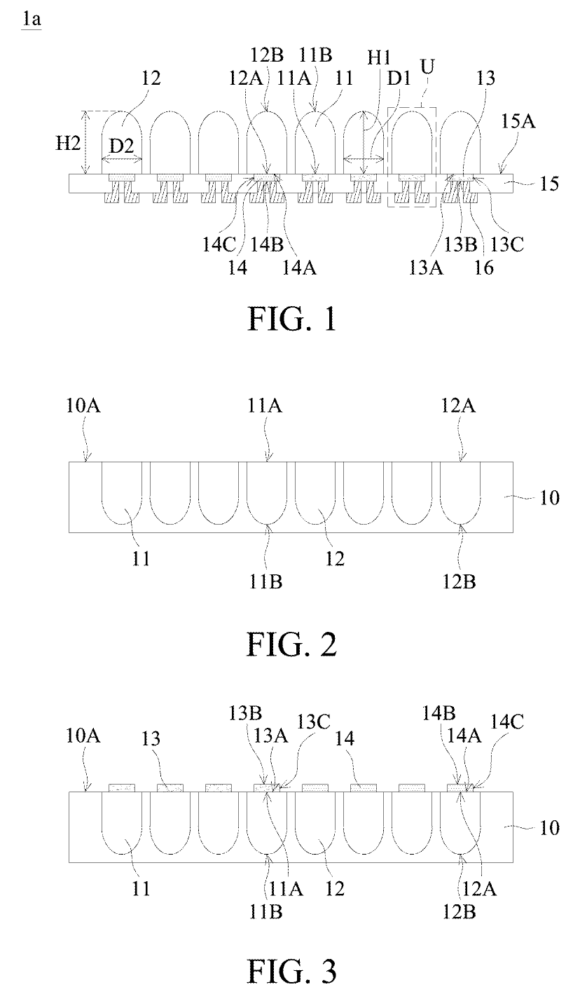

Referring to FIG. 1, a photoelectric module 1a includes an interposer layer 15, a first photoelectric element 13, a second photoelectric element 14, a first lens 11, a second lens 12, and an electrical connection structure 16. The interposer layer 15 is configured to carry components arranged thereon or embedded therein, such as the first photoelectric element 13, the second photoelectric element 14, the first lens 11, the second lens 12, and/or the electrical connection structure 16. In one embodiment, the interposer layer 15 is integrated with an integrated circuit (not shown).

The first photoelectric element 13 is embedded in the interposer layer 15 and has an optical surface 13A, an electrode surface 13B, and a side surface 13C. The optical surface 13A is used to emit or receive light, and the electrode surface 13B is provided with electrodes. In one embodiment, the optical surface 13A and the electrode surface 13B face in opposite directions, and the side surface 13C is located therebetween. The interposer layer 15 covers the side surface 13C and at least part of the electrode surface 13B and exposes the optical surface 13A. The optical surface 13A is coplanar with an upper surface 15A of the interposer layer 15.

The second photoelectric element 14 is embedded in the interposer layer 15 and has an optical surface 14A, an electrode surface 14B, and a side surface 14C. The optical surface 14A is used to emit or receive light, and the electrode surface 14B is provided with electrodes. In one embodiment, the optical surface 14A and the electrode surface 14B face in opposite directions, and the side surface 14C is located therebetween. In one embodiment, the interposer layer 15 covers the side surface 14C and at least part of the electrode surface 14B, and exposes the optical surface 14A. In one embodiment, the optical surface 14A is coplanar with the upper surface 15A of the interposer layer 15. In one embodiment, the number of first photoelectric elements 13 and the number of second photoelectric elements 14 in the photoelectric module 1a are the same. In another embodiment, the number of first photoelectric elements 13 and the number of second photoelectric elements 14 in the photoelectric module 1a are different.

In one embodiment, the first photoelectric element 13 is a light-emitting element, such as a light-emitting diode (LED) or a laser diode (LD). A plurality of first photoelectric elements 13 emits light with the same wavelength. In another embodiment, the plurality of first photoelectric elements 13 emits light with different wavelengths. In one embodiment, the second photoelectric element 14 is a light-receiving element such as a photodiode (PD). A plurality of second photoelectric elements 14 receives light with the same wavelength. In another embodiment, the plurality of second photoelectric elements 14 receives light with different wavelengths. In one embodiment, the first photoelectric element 13 and the second photoelectric element 14 are light-emitting elements, and the first photoelectric element 13 and the second photoelectric element 14 are configured to emit light with different wavelengths. In another embodiment, both the first photoelectric element 13 and the second photoelectric element 14 are light-receiving elements, and the first photoelectric element 13 and the second photoelectric element 14 are configured to receive light with different wavelengths.

In one embodiment, the first photoelectric element 13 and the second photoelectric element 14 have the same height (or thickness). In another embodiment, the first photoelectric element 13 and the second photoelectric element 14 have different dimensions; for example, the height of the second photoelectric element 14 is less than the height of the first photoelectric element 13 (not shown). When the upper surface 15A of the interposer layer 15, the optical surface 13A, and the optical surface 14A are coplanar, the electrode surface 14B of the second photoelectric element 14 is higher than the electrode surface 13B of the first photoelectric element 13.

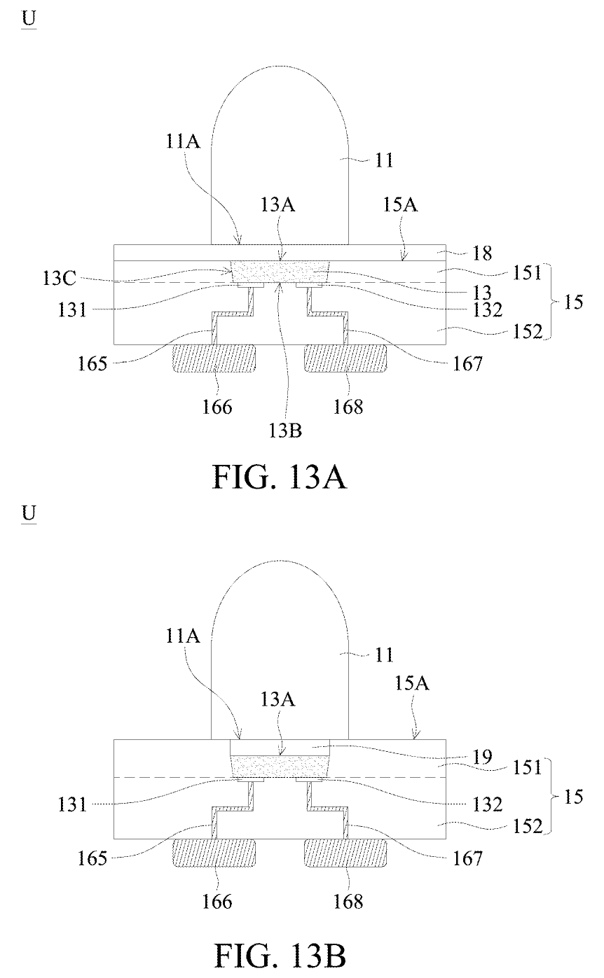

The first lens 11 is arranged on the first photoelectric element 13, and the second lens 12 is arranged on the second photoelectric element 14. In one embodiment, the first lens 11 has a flat surface 11A and a curved convex surface 11B, while the second lens 12 has a flat surface 12A and a curved convex surface 12B. The first lens 11 and the second lens 12 have a droplet profile, a cannonball-shaped profile, or a similar shape. The flat surface 11A of the first lens 11 directly contacts the first photoelectric element 13 or is connected to the optical surface 13A of the first photoelectric element 13 via an adhesive layer (such as the adhesive layer 18 shown in FIG. 13A or the adhesive layer 19 shown in FIG. 13B). The flat surface 12A of the second lens 12 directly contacts the optical surface 14A of the second photoelectric element 14 or is connected to the optical surface 14A via an adhesive layer. In one embodiment, the flat surface 11A completely covers the optical surface 13A of the first photoelectric element 13, and the flat surface 12A completely covers the optical surface 14A. In a top view, the area of the flat surface 11A of the first lens 11 is greater than or equal to the area of the optical surface 13A of the first photoelectric element 13, and the area of the flat surface 12A of the second lens 12 is greater than or equal to the area of the optical surface 14A of the second photoelectric element 14.

When the first photoelectric element 13 is a light-emitting element, the light transmittance of the first lens 11 for the light emitted from the first photoelectric element 13 is greater than or equal to 95%. In one embodiment, the first lens 11 has a numerical aperture (NA) with a value between 0.3 and 0.9, where NA = (n*D) / (2*f), D is the diameter D1 of the first lens 11, and f is the focal length of the first lens 11. In one embodiment, the emission angle or half-intensity angle of the first lens 11 is between 30° and 40°, such as 35°. In one embodiment, the diameter D1 (or width) of the first lens 11 is between 30 µm and 50 µm, such as 40 µm. In one embodiment, the height H1 of the first lens 11 is between 50 µm and 70 µm, such as 60 µm. In one embodiment, the refractive index (n) of the first lens 11 is between 1.5 and 1.7, such as 1.6. In one embodiment, when the NA of the first lens 11 is 0.3, the focal length f of the first lens 11 is approximately 107 µm. In one embodiment, a plurality of first lenses 11 is arranged in a one-to-one manner on a plurality of first photoelectric elements 13.

When the second photoelectric element 14 is a light-receiving element, the light transmittance of the second lens 12 for the light intended to be received by the second photoelectric element 14 is greater than or equal to 95%. In one embodiment, the second lens 12 has a numerical aperture (NA) with a value between 0.3 and 0.9. In one embodiment, the light collection angle or half-intensity angle of the second lens 12 is between 30° and 40°, such as 35°. In one embodiment, the diameter D2 (or width) of the second lens 12 is between 30 µm and 50 µm, such as 40 µm. In one embodiment, the height H2 of the second lens 12 is between 50 µm and 70 µm, such as 60 µm. In one embodiment, the refractive index (n) of the second lens 12 is between 1.5 and 1.7, such as 1.6. In one embodiment, when the NA of the second lens 12 is 0.3, the focal length f of the second lens 12 is approximately 107 µm. A plurality of second lenses 12 is arranged in a one-to-one manner on a plurality of second photoelectric elements 14.

In one embodiment, the first lens 11 and the second lens 12 are identical in appearance, material, and optical properties. In another embodiment, the properties of the first lens 11 and the second lens 12 are not completely the same. For example, the second lens 12 and the first lens 11 are different from each other in one or more of shape, size, material, transmittance, and NA.

The electrical connection structure 16 is arranged within the interposer layer 15. In one embodiment, the first end of the electrical connection structure 16 is connected to the electrode located on the electrode surface 13B of the first photoelectric element 13, on the electrode surface 14B of the second photoelectric element 14, or on both. The second end of the electrical connection structure 16 is exposed from the interposer layer 15. In one embodiment, the electrical connection structure 16 is a fan-out structure, wherein the first end has a smaller surface area than the second end. In one embodiment, the second end of the electrical connection structure 16 protrudes from the lower surface of the interposer layer 15. In another embodiment, the second end of the electrical connection structure 16 is coplanar with the lower surface of the interposer layer 15 (not shown).

In one embodiment, the material of the interposer layer 15 includes epoxy, silicone, polyimide (PI), polycarbonate (PC), polyethylene terephthalate (PET), polypropylene (PP), or a combination thereof. In one embodiment, the interposer layer 15 contains an opaque material to prevent or reduce light from entering/leaving the photoelectric elements 13, 14 through the interposer layer 15. The opaque material includes silicone mixed with white particles or black particles, wherein the white particles include titanium dioxide and the black particles include carbon black.

In one embodiment, the material of the light-emitting element includes: binary compound semiconductors such as GaAs, GaP, or GaN; ternary compound semiconductors such as InGaAs, AlGaAs, InGaP, AlInP, InGaN, or AlGaN; or quaternary compound semiconductors such as AlGaInAs, AlGaInP, AlInGaN, InGaAsP, InGaNAs, or AlGaAsP. The color of the light emitted by the light-emitting element depends on the material of the light-emitting element. For example, when the material of the light-emitting element includes AlGaN, it emits ultraviolet light with a peak wavelength of 250 nm to 400 nm; when the material includes InGaN, it can emit deep blue or blue light with a peak wavelength of 400 nm to 490 nm, green or yellow light with a peak wavelength of 490 nm to 550 nm, or red light with a peak wavelength of 560 nm to 650 nm; when the material includes InGaP or AlGaInP, it can emit yellow, orange, or red light with a peak wavelength of 530 nm to 700 nm; or when the material includes InGaAs, InGaAsP, AlGaAs, or AlGaInAs, it can emit infrared light with a peak wavelength of 700 nm to 1700 nm.

In one embodiment, the material of the light-receiving element includes Si, GaN, GaAs, or InGaP. In one embodiment, the material of the first lens 11 and/or the second lens 12 includes silicone. In one embodiment, the first lens 11 and/or the second lens 12 further includes an optical film, such as a wear-resistant layer, an anti-reflective layer, a Bragg reflector, or a combination thereof.

In one embodiment, the electrical connection structure 16 includes conductive oxides, metals, or alloys. Conductive oxides include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), or a combination thereof. Metals include germanium (Ge), beryllium (Be), zinc (Zn), gold (Au), nickel (Ni), or copper (Cu). Alloys include at least two selected from the aforementioned metals, such as germanium-gold-nickel (GeAuNi), beryllium-gold (BeAu), germanium-gold (GeAu), zinc-gold (ZnAu).

FIGS. 2 to 6 illustrate a manufacturing process of a photoelectric module 1a according to an embodiment of the present disclosure. Referring to FIG. 2, a temporary substrate 10, a first lens 11, and a second lens 12 are provided, wherein the first lens 11 and the second lens 12 are embedded in the temporary substrate 10. The flat surface 11A of the first lens 11 and the flat surface 12A of the second lens 12 are exposed from the temporary substrate 10 and are coplanar with the upper surface 10A of the temporary substrate 10. In one embodiment, the temporary substrate 10 includes epoxy resin, silicone, polyimide (PI), polycarbonate (PC), polyethylene terephthalate (PET), polypropylene (PP), or a combination thereof. In one embodiment, the first lens 11 and/or the second lens 12 include polymer material, photoimageable dielectric (PID), or silicone, and can be formed by photolithography, etching, or other suitable microfabrication processes.

Referring to FIG. 3, a first photoelectric element 13 is arranged on the first lens 11, and a second photoelectric element 14 is arranged on the second lens 12. The optical surface 13A of the first photoelectric element 13 faces the flat surface 11A of the first lens 11, and the optical surface 14A of the second photoelectric element 14 faces the flat surface 12A of the second lens 12. In one embodiment, the photoelectric elements 13 and 14 are directly fixed onto the lenses 11 and 12. In another embodiment, the photoelectric elements 13 and 14 are fixed onto the lenses 11 and 12 by means of an adhesive layer (for example, the adhesive layers 18, 19 shown in FIGS. 13A and 13B). In one embodiment, the first photoelectric element 13 and the second photoelectric element 14 are respectively transferred onto the lenses 11 and 12 by a mass transfer process. The mass transfer process includes a laser transfer process, a stamp transfer process, or a combination thereof.

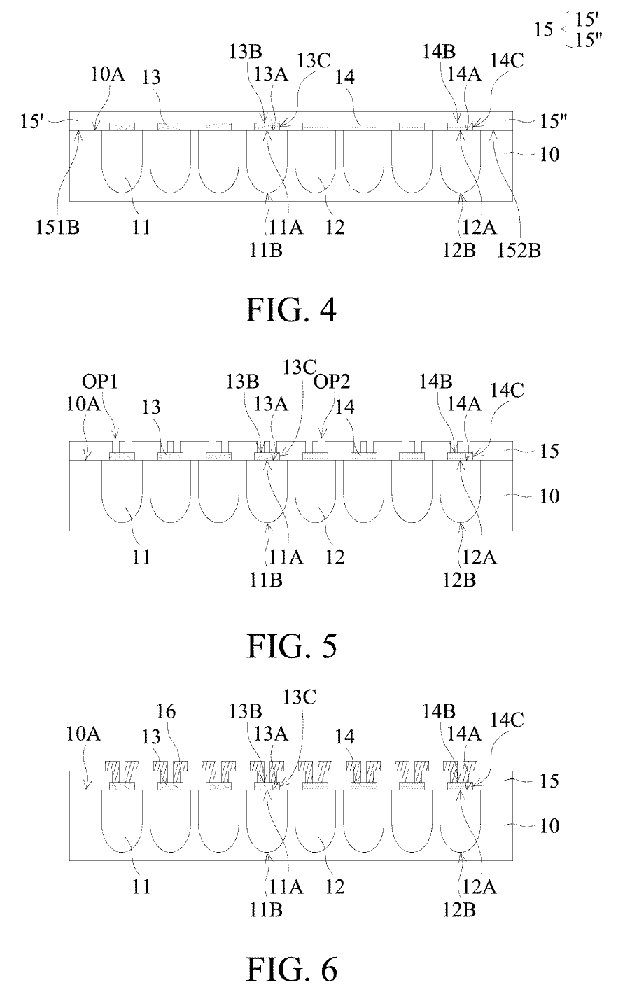

Referring to FIG. 4, an interposer layer 15 is formed on the first photoelectric element 13 and the second photoelectric element 14. The interposer layer 15 covers the side surface 13C and the electrode surface 13B of the first photoelectric element 13, as well as the side surface 14C and the electrode surface 14B of the second photoelectric element 14. In one embodiment, the interposer layer 15 is formed by printing, spray coating, other suitable processes, or a combination thereof. In one embodiment, the interposer layer 15 includes a first interposer layer 15’ and a second interposer layer 15’’, wherein the first interposer layer 15’ surrounds the first photoelectric element 13, and the second interposer layer 15’’ surrounds the second photoelectric element 14. In one embodiment, the first interposer layer 15’ and the second interposer layer 15’’ are separated by a gap (not shown). In one embodiment, when the thicknesses of the first photoelectric element 13 and the second photoelectric element 14 are different, the thicknesses of the first interposer layer 15’ and the second interposer layer 15’’ are also different (not shown). In one embodiment, when the first photoelectric element 13 is taller than the second photoelectric element 14, the thickness of the first interposer layer 15’ is greater than that of the second interposer layer 15’’.

Referring to FIG. 5, a first opening OP1 is formed in the interposer layer 15 to expose the electrode surface 13B of the first photoelectric element 13, and a second opening OP2 is formed in the interposer layer 15 to expose the electrode surface 14B of the second photoelectric element 14. In one embodiment, the first photoelectric element 13 includes a first electrode and a second electrode located on the electrode surface 13B (not shown), and the second photoelectric element 14 includes a third electrode and a fourth electrode located on the electrode surface 14B (not shown). In one embodiment, two first openings OP1 are provided on the first photoelectric element 13 to respectively expose the first electrode and the second electrode, and two second openings OP2 are provided on the second photoelectric element 14 to respectively expose the third electrode and the fourth electrode. In one embodiment, the first opening OP1 and/or the second opening OP2 are formed in the interposer layer 15 by etching, drilling, or photolithography processes.

Referring to FIG. 6, an electrical connection structure 16 is formed on the first photoelectric element 13 and the second photoelectric element 14. The electrical connection structure 16 is arranged via the first opening OP1 on the first electrode and the second electrode of the first photoelectric element 13, and protrudes from the interposer layer 15. Similarly, the electrical connection structure 16 is arranged via the second opening OP2 on the third electrode and the fourth electrode of the second photoelectric element 14, and protrudes from the interposer layer 15. In one embodiment, the electrical connection structure 16 is formed by electroplating, chemical plating, chemical vapor deposition (CVD), physical vapor deposition (PVD), or other processes.

After completing the above step, the process returns to FIG. 1 to illustrate the final configuration. Returning to FIG. 1, the temporary substrate 10 is removed to expose the first lens 11 and the second lens 12, and the entire structure is inverted to obtain the photoelectric module 1a shown in FIG. 1. The temporary substrate 10 can be separated from the interposer layer 15 by grinding, etching, peeling, or other methods.

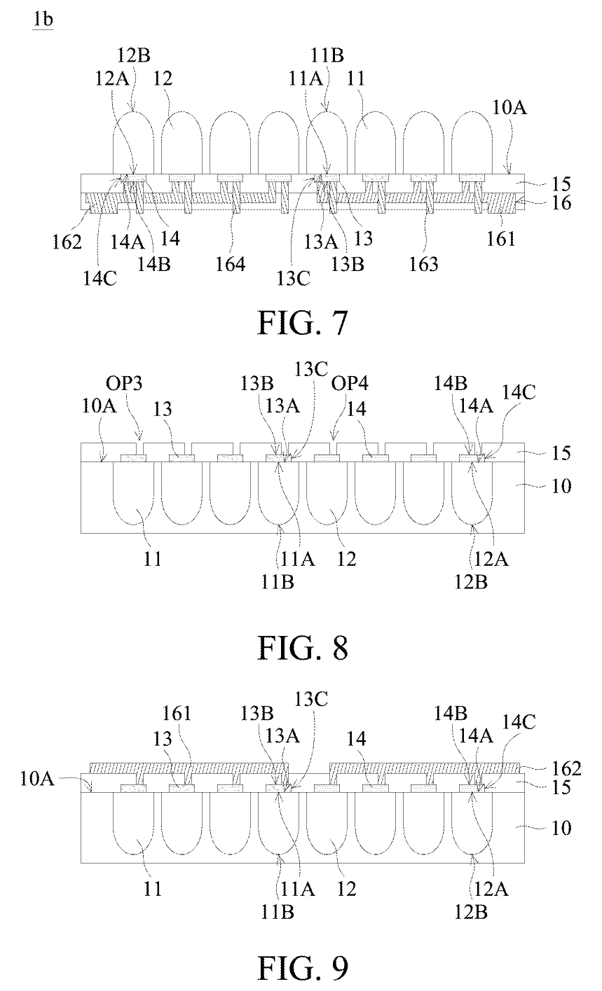

Referring to FIG. 7, FIG. 7 illustrates a photoelectric module 1b according to another embodiment of the present disclosure. The photoelectric module 1b includes the interposer layer 15, the first photoelectric element 13, the second photoelectric element 14, the first lens 11, the second lens 12, and the electrical connection structure 16 mentioned above, wherein the descriptions of each component can be referred to above. The electrical connection structure 16 in the photoelectric module 1b further includes a common electrode portion 161 and a common electrode portion 162. The common electrode portion 161 is simultaneously connected to the first electrodes of the plurality of first photoelectric elements 13, and the common electrode portion 162 is simultaneously connected to the third electrodes of the plurality of second photoelectric elements 14.

Referring to FIGS. 8 to 12, FIG. 8 shows a structure following that of FIG. 4. As shown in FIG. 8, a third opening OP3 is formed in the interposer layer 15 to expose the first electrode (not shown) on the electrode surface 13B of the first photoelectric element 13, and a fourth opening OP4 is formed in the interposer layer 15 to expose the third electrode (not shown) on the electrode surface 14B of the second photoelectric element 14.

Referring to FIG. 9, a common electrode portion 161 of the electrical connection structure 16 is formed on the plurality of first photoelectric elements 13, and a common electrode portion 162 of the electrical connection structure 16 is formed on the plurality of second photoelectric elements 14. The common electrode portion 161 protrudes from the interposer layer 15 and extends along the upper surface of the interposer layer 15, and the common electrode portion 162 protrudes from the interposer layer 15 and extends along the upper surface of the interposer layer 15.

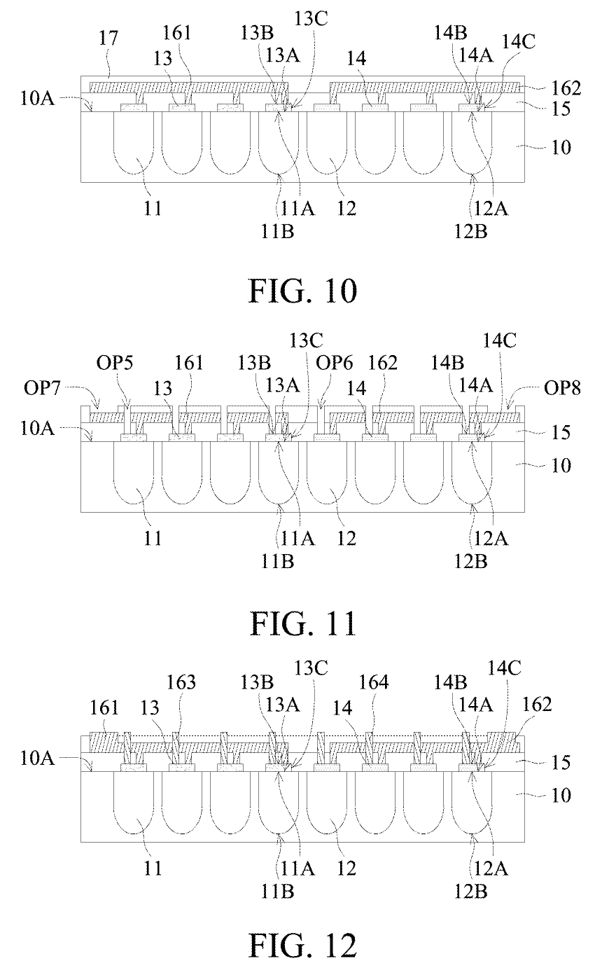

Referring to FIG. 10, an interposer layer 17 is formed to cover the common electrode portion 161 and the common electrode portion 162. In one embodiment, the material of the interposer layer 17 is similar or identical to that of the interposer layer 15, or the interposer layer 15 and the interposer layer 17 are formed using the same or similar processes.

Referring to FIG. 11, a fifth opening OP5 is formed in the interposer layer 15 and the interposer layer 17 to expose the second electrode (shown) of the first photoelectric element 13, and a sixth opening OP6 is formed in the interposer layer 15 and the interposer layer 17 to expose the fourth electrode (not shown) of the second photoelectric element 14. It should be noted that in FIG. 11, the fifth opening OP5 and the sixth opening OP6 do not actually cut off or separate the common electrode portions 161 and 162.

In one embodiment, a seventh opening OP7 and an eighth opening OP8 are formed in the interposer layer 17 to expose the common electrode portion 161 and the common electrode portion 162. In one embodiment, the fifth opening OP5, the sixth opening OP6, the seventh opening OP7, and the eighth opening OP8 are formed together in the same process.

Referring to FIG. 12, a plurality of electrode portions 163 is arranged on the second electrodes of the first photoelectric elements 13 via multiple fifth openings OP5, respectively, and a plurality of electrode portions 164 is arranged on the fourth electrodes of the second photoelectric elements 14 via multiple sixth openings OP6, respectively. The electrode portions 163 and 164 protrude outward from the interposer layer 17.

In one embodiment, a conductive material is further formed on the common electrode portion 161 and the common electrode portion 162, such that the common electrode portions 161 and 162 each have a surface exposed from the interposer layer 17 through the seventh opening OP7 and the eighth opening OP8. In one embodiment, any two or more of the top surface of the common electrode portion 161, the top surface of the common electrode portion 162, the top surface of the electrode portion 163, and the top surface of the electrode portion 164 are coplanar.

Returning to FIG. 7, the temporary substrate 10 is removed to expose the first lens 11 and the second lens 12, and the entire structure is inverted to obtain the photoelectric module 1b shown in FIG. 7.

Referring to FIGS. 13A and 13B. FIGS. 13A and 13B illustrate a photoelectric unit U according to different embodiments of the present disclosure. The composition of the photoelectric unit U can be referred to in FIG. 1 and the related description. Although the drawings take the first photoelectric element 13 and the first lens 11 as examples, one of ordinary skill in the art will understand that these detailed structures are also applicable to the second photoelectric element 14 and the second lens 12.

As shown in FIG. 13A, in one embodiment, the interposer layer 15 includes a first sub-interposer layer 151 and a second sub-interposer layer 152. The first sub-interposer layer 151 surrounds the side surface 13C of the first photoelectric element 13, and the second sub-interposer layer 152 covers the electrode surface 13B of the first photoelectric element 13. In one embodiment, the electrical connection structure 16 includes a first electrical connector 165 electrically connected to a first electrode 131, and a second electrical connector 167 electrically connected to a second electrode 132. The first electrical connector 165 and the second electrical connector 167 are arranged in the second sub-interposer layer 152. The electrical connection structure 16 further includes a first contact 166 and a second contact 168, and the first contact 166 and the second contact 168 each have a surface exposed from the second sub-interposer layer 152. The first contact 166 is connected to the first electrical connector 165, and the second contact 168 is connected to the second electrical connector 167. In one embodiment, the first electrical connector 165 and the second electrical connector 167 have portions extending along the horizontal direction and portions extending along the vertical direction. In another embodiment, the first sub-interposer layer 151 covers the side surface 13C and the electrode surface 13B of the first photoelectric element 13 and encapsulates portions of the electrical connectors 165 and 167 (not shown), and the portions of the electrical connectors 165 and 167 extending along the horizontal direction are located at the interface between the first sub-interposer layer 151 and the second sub-interposer layer 152. In another embodiment, the first electrical connector 165 and the second electrical connector 167 have only portions extending along the vertical direction, as shown in FIG. 1.

In one embodiment, a light-transmissive adhesive layer 18 is arranged between the first lens 11 and the first photoelectric element 13 to secure the first lens 11 and the first photoelectric element 13 together. For example, after the structure shown in FIG. 2, the adhesive layer 18 is formed on the first lens 11 and the temporary substrate 10. Subsequently, the steps following FIG. 3 are sequentially performed to form the structure shown in FIG. 13A. The adhesive layer 18 covers the first photoelectric element 13 and the interposer layer 15, and the optical surface 13A of the first photoelectric element 13 is coplanar with the upper surface 15A of the interposer layer 15. The flat surface 11A of the first lens 11 contacts the adhesive layer 18.

As shown in FIG. 13B, in another embodiment, a light-transmissive adhesive layer 19 is arranged between the first lens 11 and the first photoelectric element 13. After the structure shown in FIG. 2, the adhesive layer 19 is formed on the first lens 11 to adhere the first photoelectric element 13. Subsequently, the portion of the adhesive layer 19 not covering the first photoelectric element 13 is removed. Thereafter, the steps following FIG. 4 are performed to form the structure shown in FIG. 13B. The adhesive layer 19 covers the first photoelectric element 13 but exposes the interposer layer 15. The optical surface 13A of the first photoelectric element 13 is not coplanar with the upper surface 15A of the interposer layer 15, and the flat surface 11A of the first lens 11 covers the interposer layer 15 and the adhesive layer 19.

In another embodiment, the first lens 11 and/or the second lens 12 are formed of an adhesive colloid and are directly connected to the photoelectric elements 13 and 14, thereby omitting the aforementioned adhesive layers 18 and 19.

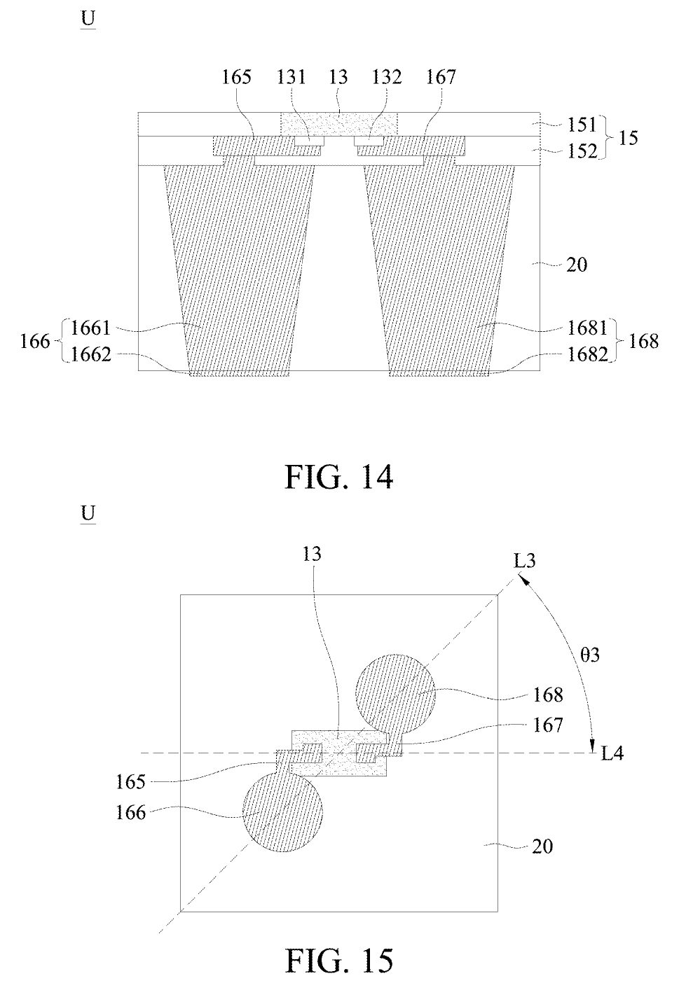

Referring to FIGS. 14 and 15. FIGS. 14 and 15 illustrate a side view and a bottom view of a photoelectric unit U according to one embodiment. For clarity, FIG. 14 omits the first lens 11 and the adhesive layer. In FIG. 15, although the first photoelectric element 13 and the electrical connectors 165 and 167 are covered by a filler material layer 20, they are represented by solid lines.

As shown in FIG. 14, in one embodiment, the photoelectric module further includes a filler material layer 20 arranged over the interposer layer 15. The second sub-interposer layer 152 is located between the filler material layer 20 and the first sub-interposer layer 151. In one embodiment, the first contact 166 includes a first conductive pillar 1661 and a first pad 1662, and the second contact 168 includes a second conductive pillar 1681 and a second pad 1682. The first conductive pillar 1661 and the second conductive pillar 1681 are arranged in the filler material layer 20, and the first pad 1662 and the second pad 1682 are exposed from the filler material layer 20.

In one embodiment, the conductive pillars 1661 and 1681 are formed by electroplating, and their thickness is several times to several tens of times greater than that of the pads 1662 and 1682. In one embodiment, the thickness of the conductive pillars 1661 and 1681 ranges from 5 μm to 100 μm. In one embodiment, the material of the conductive pillars 1661 and 1681 includes copper, and the material of the pads 1662 and 1682 includes titanium, nickel, gold, or any combination thereof.

In one embodiment, the material of the filler material layer 20 includes polyimide (PI), epoxy resin, or a combination thereof. In one embodiment, the material of the filler material layer 20 includes epoxy molding compound (EMC). In one embodiment, the material of the filler material layer 20 is the same as or similar to that of the interposer layer 17, and/or the filler material layer 20 is formed using the same or similar process as that used for forming the interposer layer 17.

In one embodiment, the light transmittance of the filler material layer 20 (for example, the transmittance for light emitted/received by the photoelectric element, the transmittance for visible light) is less than or equal to 70%, for example, 70%, 65%, 60%, 55%, 50%, 45%, 40%, 35%, 30%, 25%, 20%, or any range among these values. In one embodiment, the filler material layer 20 contains a material having a light absorption rate greater than 90% for light emitted/received by the photoelectric element or visible light, and the filler material layer 20 appears black. In one embodiment, the black-appearing filler material layer 20 includes a colorless or yellow epoxy resin and black particles dispersed therein, wherein the black particles contain carbon black. In one embodiment, the hardness of the filler material layer 20 is greater than that of the interposer layer 15.

Referring to FIG. 15, in one embodiment, the first electrical connector 165 and the second electrical connector 167 serve as a redistribution layer, and the first contact 166 and the second contact 168 are arranged at two corners located around opposite ends of a diagonal of the first photoelectric element 13. As shown in FIG. 15, in one embodiment, the photoelectric unit U is intersected by a third virtual extension line L3 and a fourth virtual extension line L4. The center points of the first contact 166 and the second contact 168 are located on the third virtual extension line L3, and the two electrodes of the first photoelectric element 13 are located on the fourth virtual extension line L4. The third virtual extension line L3 and the fourth virtual extension line L4 are intersected with each other by a third angle θ3, wherein the third angle θ3 can be 30°, 45°, or 60°. In one embodiment, the third angle θ3 is 45°. In one embodiment, as shown in FIG. 15, the area of the first contact 166 is greater than the area of the first photoelectric element 13. In another embodiment, along the direction of the fourth virtual extension line L4, the width of the first photoelectric element 13 is smaller than the width of the first contact 166.

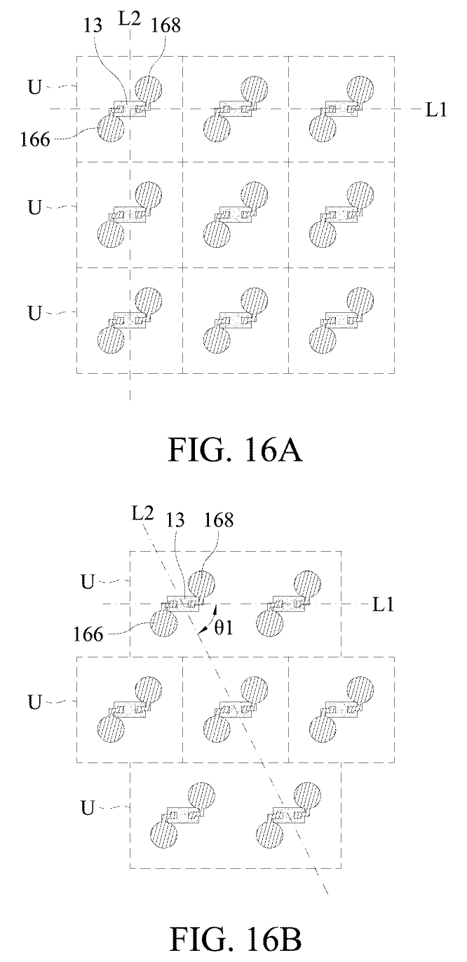

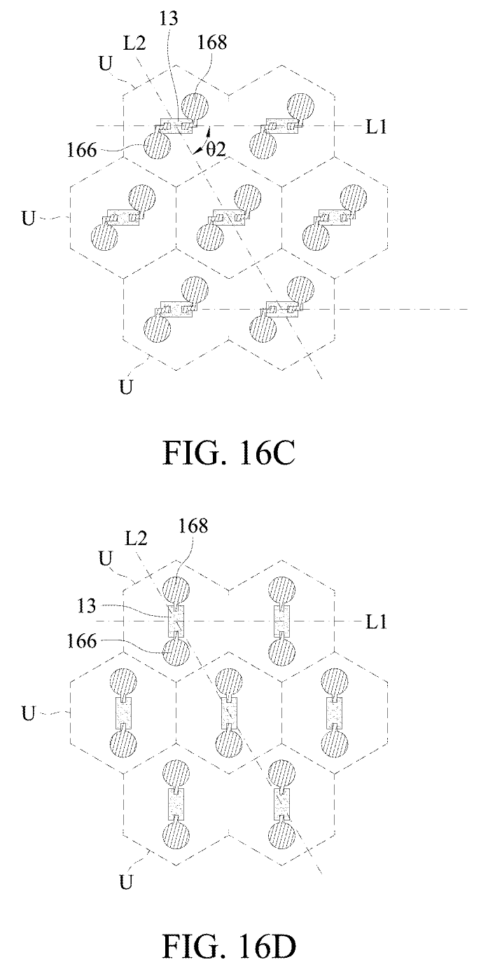

Referring to FIGS. 16A to 16D. FIGS. 16A to 16D illustrate an arrangement of the photoelectric units U in different embodiments of the present disclosure. As shown in FIG. 16A, in one embodiment, the first contact 166 and the second contact 168 of the photoelectric unit U are respectively located at two corners located around opposite ends of a diagonal of the first photoelectric element 13 (as shown in FIG. 15), and multiple photoelectric units U are arranged along a first virtual extension line L1 and a second virtual extension line L2. The first virtual extension line L1 is parallel to the long side of the first photoelectric element 13, and multiple photoelectric units U are arranged in a row along the first virtual extension line L1. The second virtual extension line L2 is defined as a virtual straight line that is not parallel to the first virtual extension line L1. The photoelectric units U located in the same row are arranged along the second virtual extension line L2. In one embodiment, the first virtual extension line L1 and the second virtual extension line L2 intersect each other at a non-90-degree angle, for example, similar to the fourth virtual extension line L4 and the third virtual extension line L3 shown in FIG. 15. In one embodiment, the first virtual extension line L1 and the second virtual extension line L2 are perpendicular to each other, and the multiple photoelectric units U are arranged in a matrix.

As shown in FIG. 16B, in another embodiment, the first virtual extension line L1 and the second virtual extension line L2 are not perpendicular to each other, and are intersected with each other by a first angle θ1. For example, the first angle θ1 is greater than 0° and less than 90°, such as 10°, 20°, 30°, 40°, 50°, 60°, 70°, or 80°. In one embodiment, the first angle θ1 is 60°.

As shown in FIG. 16C, in another embodiment, the photoelectric unit U has a hexagonal outline, and multiple photoelectric units U are closely arranged. The first virtual extension line L1 and the second virtual extension line L2 are intersected with each other by a second angle θ2, and the second angle θ2 is substantially 60°. In other words, the multiple photoelectric units U are arranged in a hexagonal close-packing (HCP) configuration.

As shown in FIG. 16D, in another embodiment, the multiple photoelectric units U are arranged in a hexagonal close-packing (HCP) configuration, and in each photoelectric unit U, the first contact 166 and the second contact 168 are respectively located on opposite sides of the first photoelectric element 13, for example, on opposite sides along the long side direction of the first photoelectric element 13.

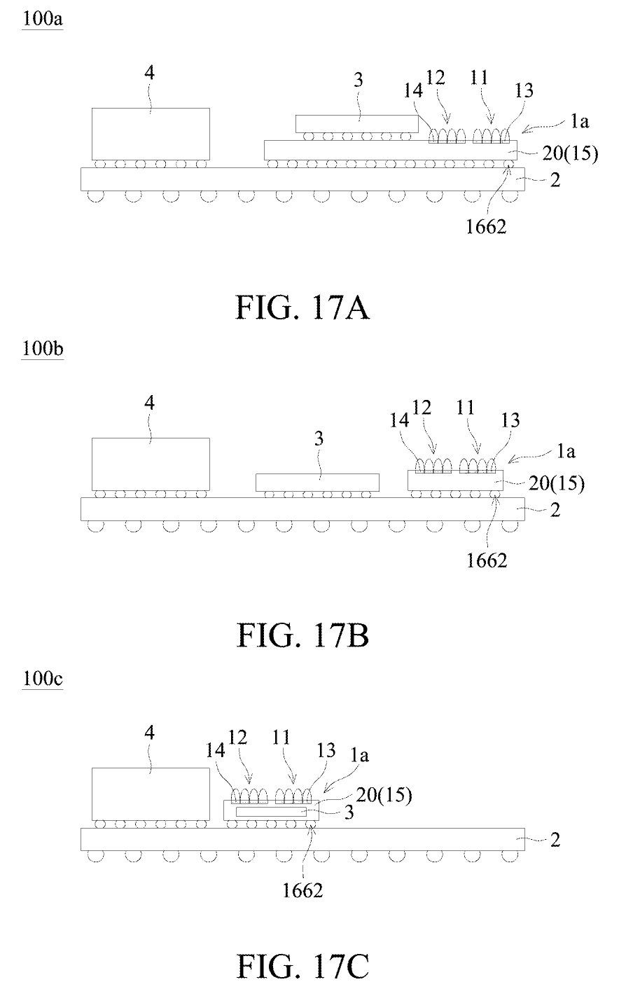

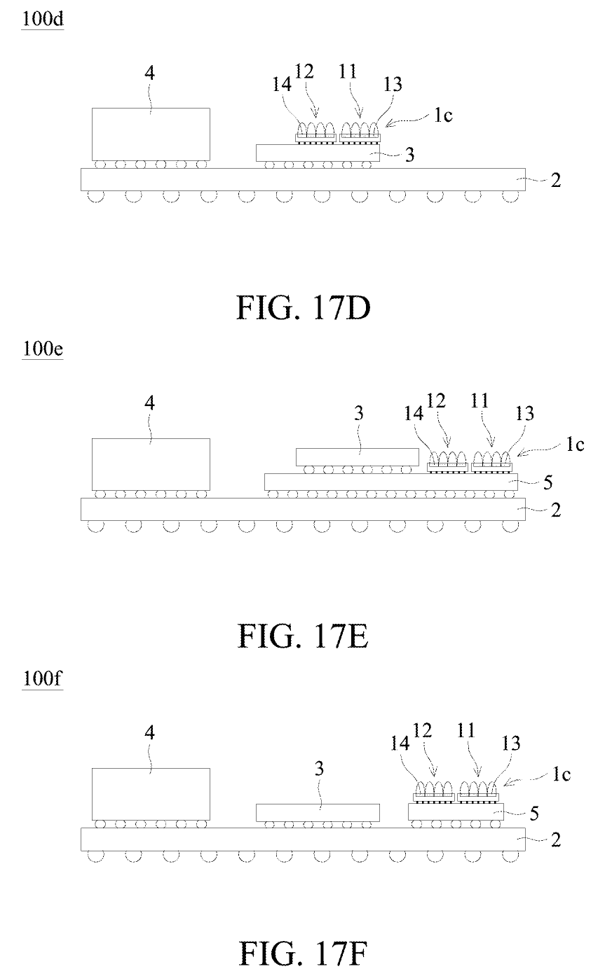

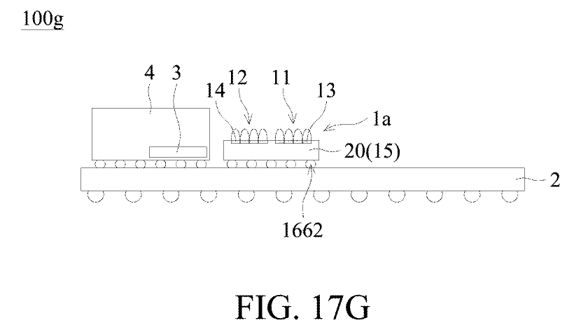

Referring to FIGS. 17A to 17G, in one embodiment, the photoelectric module 1a is integrated with other electronic components to form photoelectric systems 100a-100g to achieve specific functions. In practical applications, another photoelectric system (not shown) transmits or exchanges optical signals through an optical transmission element (not shown), wherein the optical transmission element is optically coupled to the photoelectric module 1a for transmitting optical signals.

As shown in FIG. 17A, the photoelectric system 100a includes a photoelectric module 1a, an interposer 2, an electrical integrated circuit (EIC) 3, and an active component 4. The photoelectric module 1a is arranged on the interposer 2, the electrical integrated circuit 3 is arranged on the photoelectric module 1a, and the active component 4 is arranged on the interposer 2. The active component 4 is electrically connected to the electrical integrated circuit 3 via the interposer 2 and the interposer layer 15 in the photoelectric module 1a, and controls the operation of the photoelectric module 1a through the electrical integrated circuit 3. The operation includes light emission, light reception, or both.

In one embodiment, the photoelectric module 1a adopts the first photoelectric element 13 as shown in FIG. 14. The photoelectric module 1a includes the filler material layer 20, conductive pillars 1661 and 1681 arranged in the filler material layer 20, and pads 1662 and 1682 exposed from the filler material layer 20, so as to be more securely bonded to the interposer 2. For simplicity, only the filler material layer 20 and the first pad 1662 are shown here, and other components and their reference numerals are omitted.

In one embodiment, the interposer 2 includes a silicon interposer, and the conductive structure (via) is formed by a through-silicon via (TSV). The electrical integrated circuit 3 includes a digital signal processor (DSP), a driver, or a transimpedance amplifier (TIA). The active component 4 includes a central processing unit (CPU), a graphics processing unit (GPU), or an application-specific integrated circuit (ASIC).

As shown in FIG. 17B, in another embodiment, the electrical integrated circuit 3 of the photoelectric system 100b is arranged on the interposer 2. The active component 4 is electrically connected to the electrical integrated circuit 3 via the interposer 2, and the electrical integrated circuit 3 is electrically connected to the photoelectric module 1a via the interposer 2.

As shown in FIG. 17C, in another embodiment, the electrical integrated circuit 3 of the photoelectric system 100c is arranged within the photoelectric module 1a. The active component 4 is electrically connected to the electrical integrated circuit 3 via the photoelectric module 1a. In one embodiment, when forming the interposer layer 15 as shown in FIG. 4, the electrical integrated circuit 3 is embedded in the interposer layer 15. In one embodiment, in the photoelectric modules shown in FIGS. 17A-17C, the photoelectric module 1a is replaced with the photoelectric module 1b (not shown).

As shown in FIG. 17D, in another embodiment, the photoelectric module 1c of the photoelectric system 100d is similar to the photoelectric module 1a or 1b described above, but the interposer layer 15 of the photoelectric module 1c is divided into a separate first interposer layer 15’ and a second interposer layer 15’’ for carrying the first photoelectric element 13 or the second photoelectric element 14, respectively. The first photoelectric element 13 is a light-emitting element, and the second photoelectric element 14 is a light-receiving element. In other words, the light-emitting element and the light-receiving element are carried by different interposer layers. The photoelectric module 1c is arranged on the electrical integrated circuit 3, and the electrical integrated circuit 3 is then arranged on the interposer 2. The active component 4 is electrically connected to the electrical integrated circuit 3 via the interposer 2, and controls the operation of the photoelectric module 1c through the electrical integrated circuit 3.

As shown in FIG. 17E, in another embodiment, both the photoelectric module 1c and the electrical integrated circuit 3 of the photoelectric system 100e are arranged on an interposer 5. The active component 4 is electrically connected to the electrical integrated circuit 3 via the interposer 2 and the interposer 5, and controls the operation of the photoelectric module 1c through the electrical integrated circuit 3. In one embodiment, the interposer 5 includes a silicon interposer or a glass interposer, and the conductive structure is formed by a through-silicon via (TSV) or a through-glass via (TGV).

As shown in FIG. 17F, in another embodiment, the photoelectric module 1c of the photoelectric system 100f is arranged on the interposer 5, and the interposer 5 and the electrical integrated circuit 3 are arranged on the interposer 2. The active component 4 is electrically connected to the electrical integrated circuit 3 via the interposer 2, and controls the operation of the photoelectric elements in the photoelectric module 1c through the electrical integrated circuit 3.

As shown in FIG. 17G, in another embodiment, the electrical integrated circuit 3 of the photoelectric system 100g is arranged within the active component 4. The active component 4 is directly electrically connected to the electrical integrated circuit 3, and the active component 4 and the photoelectric module 1c are electrically connected via the interposer 2.

Referring again to FIG. 7, FIG. 7 shows eight photoelectric elements, referred to as four first photoelectric elements 13 and four second photoelectric elements 14, but the present disclosure is not limited thereto. In one embodiment, the eight photoelectric elements from right to left are respectively referred to as the first photoelectric element, the second photoelectric element, the third photoelectric element... and the eighth photoelectric element. In other words, the aforementioned two first photoelectric elements 13 can be referred to as the “first” and “second” photoelectric elements. In another embodiment, the aforementioned two second photoelectric elements 14 can be referred to as the “first” and “second” photoelectric elements.

As described above, the present disclosure provides a photoelectric module and a method for manufacturing the same, in which the manufacturing process of the photoelectric module is greatly simplified and the manufacturing difficulty is reduced by employing a “RDL last” (Redistribution Layer Last) approach. This allows the photoelectric module to be easily integrated with or separated from other electronic devices. In addition, the present disclosure further provides several photoelectric systems including the photoelectric module to specifically illustrate some possible applications of the disclosure.

As long as they do not contradict the spirit of the invention or cause conflict, the components of the embodiments of the present disclosure may be freely mixed and matched. Furthermore, the scope of protection of the present disclosure is not limited to the processes, machines, manufacturing methods, compositions of matter, apparatus, methods, and steps described in the specific embodiments disclosed herein. Any processes, machines, manufacturing methods, compositions of matter, apparatus, methods, and steps - whether currently known or developed in the future - that can be understood by those of ordinary skill in the art from the teachings of the present disclosure and that perform substantially the same function or achieve substantially the same result as those described in the embodiments herein, may also be utilized in accordance with the present disclosure. Therefore, the scope of protection of the present disclosure includes the aforementioned processes, machines, manufacturing methods, compositions of matter, apparatus, methods, and steps. Any embodiment or claim of the present disclosure is not required to achieve all of the objectives, advantages, and/or features disclosed herein.

Several embodiments have been outlined above so that those skilled in the art may better understand the concepts of the embodiments of the present disclosure. It should be understood by those skilled in the art that, based on the embodiments of the present disclosure, other processes and structures may be designed or modified to achieve the same purposes and/or advantages as those of the embodiments described herein. It should also be understood by those skilled in the art that such equivalent processes and structures do not depart from the spirit and scope of the present disclosure, and that various changes, substitutions, and modifications can be made without departing from the spirit and scope of the disclosure.

What is claimed is:

1. A method of manufacturing a photoelectric module, comprising:
providing a temporary substrate, a first lens, and a second lens, wherein the first lens and the second lens are embedded in the temporary substrate;
arranging a first photoelectric element on the first lens;
arranging a second photoelectric element on the second lens;
forming an electrical connection structure on the first photoelectric element and the second photoelectric element; and
removing the temporary substrate to expose the first lens and the second lens.

2. The method of claim 1, further comprising:
forming an interposer layer over the first photoelectric element and the second photoelectric element before forming the electrical connection structure.

3. The method of claim 2, wherein the interposer layer covers side surfaces of the first photoelectric element and the second photoelectric element.

4. The method of claim 2, wherein the step of forming the interposer layer further comprises:
embedding an electrical integrated circuit in the interposer layer.

5. The method of claim 2, further comprising:
bonding an electrical integrated circuit to the interposer layer.

6. The method of claim 2, wherein the interposer layer comprises epoxy resin, silicone, or polyimide.

7. The method of claim 2, wherein the interposer layer comprises a first interposer layer and a second interposer layer, the first interposer layer surrounding the first photoelectric element, and the second interposer layer surrounding the second photoelectric element.

8. The method of claim 1, wherein the first photoelectric element is a light-emitting element, and the second photoelectric element is a light-receiving element.

9. The method of claim 1, wherein the electrical connection structure comprises a common electrode portion electrically connected to the first photoelectric element and the second photoelectric element.

10. The method of claim 1, wherein the first lens has a numerical aperture (NA) with a value between 0.3 and 0.9.

11. A photoelectric module, comprising:
an interposer layer;
a first virtual extension line and a second virtual extension line, not parallel to each other in a bottom view;
a first photoelectric element, embedded in the interposer layer, and having a first side parallel to the first virtual extension line; and
an electrical connection structure, electrically connected to the first photoelectric element, and comprising a first contact and a second contact which both overlap with the second virtual extension line and are arranged below the interposer layer.

12. The photoelectric module of claim 11, wherein the first virtual extension line and the second virtual extension line are intersected with each other by an acute angle.

13. The photoelectric module of claim 11, wherein, in the bottom view, the first contact and the second contact are located at two opposite sides of the first photoelectric element.

14. The photoelectric module of claim 11, further comprising a filler material layer located below the interposer layer, and the first contact has a surface exposed from the filler material layer.

15. The photoelectric module of claim 14, wherein the first contact comprises a first conductive pillar and a first pad, and the filler material layer surrounds the first conductive pillar and exposes the first pad.

16. The photoelectric module of claim 11, wherein the interposer layer comprises a first sub-interposer layer and a second sub-interposer layer, the first sub-interposer layer surrounds the first photoelectric element, and the second sub-interposer layer is located below the first sub-interposer layer.

17. The photoelectric module of claim 16, wherein the electrical connection structure further comprises a first electrical connector electrically connected to the first contact, and the first electrical connector has a top surface exposed from the second sub-interposer layer.

18. The photoelectric module of claim 11, further comprising a second photoelectric element, wherein, in the bottom view, the first photoelectric element and the second photoelectric element overlap with the first virtual extension line.

19. The photoelectric module of claim 18, further comprising a third photoelectric element, and a third virtual extension line overlapping the first photoelectric element and the third photoelectric element, wherein the first virtual extension line is not perpendicular to the third virtual extension line.

20. The photoelectric module of claim 19, wherein the first virtual extension line and the third virtual extension line are intersected with each other by an acute angle.
